(19) United States
(12) Patent Application Publication
(10) Pub. No.: US 2010/0148831 A1
(43) Pub. Date: Jun. 17, 2010

(54) BUFFER WITH REMOTE CASCODE TOPOLOGY

(75) Inventors: Stanley Bo-Ting Wang, Cupertino, CA (US); Honglei Wu, Sunnyvale, CA (US); Thomas Lee, Burlingame, CA (US)

Correspondence Address: THE MUELLER LAW OFFICE, P.C., 12951 Harwick Lane, San Diego, CA, 92130, US

(73) Assignee: ZEROG WIRELESS, INC., Sunnyvale, CA (US)

(21) Appl. No.: 12/335,525

(22) Filed: Dec. 15, 2008

(51) Int. Cl. H03K 3/00

(52) U.S. Cl. 327/110; 327/108; 327/111

(57) ABSTRACT

A buffer circuit is described for buffering signals between a circuit element and a load. The buffer includes a main transistor and a cascode transistor, as well as a distribution line for transferring signals over a distance between the circuit element and the load. The buffer is arranged in a remote cascode topology such that the cascode transistor is located substantially adjacent to the load and remote from the main transistor. The distribution line transfers signals over the distance from the main transistor to the cascode transistor. This remote cascode topology makes it possible to significantly reduce the power consumption of the buffer—as compared to conventional buffers—while maintaining the maximum bandwidth possible.

The present invention relates generally to buffers, and more specifically to buffers with remote cascode topologies.

### BACKGROUND OF THE INVENTION

Buffers are commonly used in electronic circuits to provide increased current and/or voltage capacity for a signal. In wireless communications transceivers, for example, buffers may be utilized to increase signal capacity before a signal is up or down converted by a transmitter or receiver. One example of such a buffer is an LO buffer and is typically implemented between the local oscillator (LO) output of a frequency synthesizer and the corresponding up or down conversion circuit.

Various attempts have been made in the prior art to improve buffer circuits. The use of cascode topologies, for example, improves the performance of buffers. Cascode topologies include a stacked (or cascoded) transistor on top of the main transistor of the buffer. Cascode topologies generally improve the input/output isolation of a buffer and thereby help prevent unwanted oscillations. Cascode topologies also help minimize so-called Miller effects and lower the input capacitance of a buffer. Cascode topologies provide an improvement over conventional buffer circuits. Nonetheless, in high-frequency applications, buffers tend to consume a significant portion of the total power consumed by a transceiver, and there remains a continuing need for methods and apparatuses for reducing the power consumption of buffers.

### SUMMARY OF THE INVENTION

In one aspect of the invention, a method is provided for buffering a signal between a circuit element and a load with a cascode buffer. The method includes the steps of (a) locating a cascode transistor of the cascode buffer substantially adjacent to the load and remote from a main transistor of the cascode buffer; and (b) transferring signals from the main transistor to the cascode transistor via a distribution line.

In another aspect of the invention, a transmitter is provided. The transmitter includes a frequency synthesizer with a local oscillator (LO) that generates an LO-output signal comprising a high-frequency periodic signal. The transmitter also includes an up-conversion circuit for up-converting signals to be transmitted by an antenna. The transmitter also includes a buffer circuit for buffering the LO-output signal between the frequency synthesizer and the up-conversion circuit. The buffer circuit includes a main transistor, a cascode transistor and a distribution line for transferring signals over a distance. The cascode transistor of the buffer circuit is located substantially adjacent to the up-conversion circuit and substantially remote from the frequency synthesizer. The distribution line connects the drain of the main transistor to the source of the cascode transistor.

In yet another aspect of the invention, a communications terminal is provided. The communications terminal includes a frequency synthesizer with a local oscillator (LO) that generates an LO-output signal comprising a high-frequency periodic signal. The communications terminal also includes a down-conversion circuit for down-converting signals received by an antenna. The communications terminal also includes a buffer circuit for buffering the LO-output signal between the frequency synthesizer and the down-conversion circuit. The buffer circuit includes a main transistor, a cascode transistor and a distribution line for transferring signals over a distance. The cascode transistor of the buffer circuit is located substantially adjacent to the down-conversion circuit and substantially remote from the frequency synthesizer. The distribution line connects the drain of the main transistor to the source of the cascode transistor.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 illustrates a conventional NMOS common-source cascode buffer with a resistive load.

FIG. 2 illustrates a remote cascode LO buffer that is consistent with an exemplary embodiment of the present invention.

FIG. 3 illustrates a graph of the effect of changes in the capacitance dC on the bandwidth of an LO buffer with resistive load.

FIG. 4 illustrates a conventional NMOS common-source cascode buffer with an inductive load.

FIG. 5 illustrates a remote cascode LO buffer consistent with an exemplary embodiment of the present invention.

FIG. 6 illustrates the effect of changes in the capacitance dC on the transfer function of an LO buffer with inductive load.

FIG. 7 illustrates a remote cascode LO buffer that is consistent with an additional embodiment of the present invention.

FIG. 8 illustrates the effect of changes in the resistance Rg on the bandwidth of an LO buffer with resistive load.

### DETAILED DESCRIPTION

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For example, features illustrated or described as part of one embodiment may be used on another embodiment to yield a still further embodiment. Thus, it is intended that the present subject matter covers such modifications and variations as come within the scope of the appended claims and their equivalents.

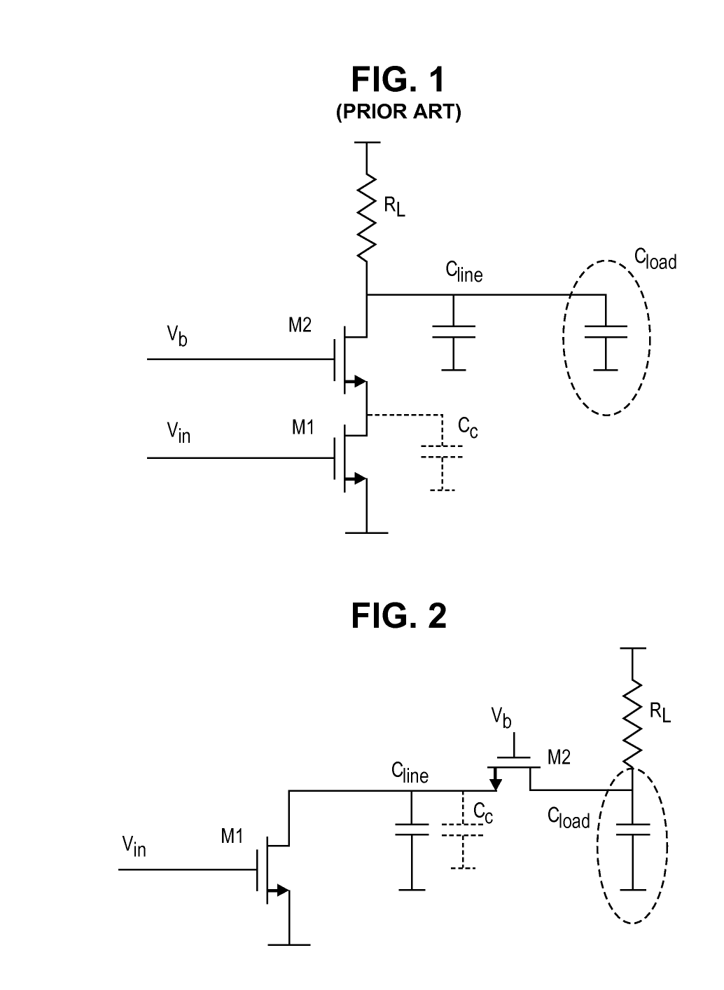

FIG. 1 illustrates a conventional NMOS common-source cascode buffer with a resistive load. The buffer includes a main transistor M1 and a cascode transistor M2. The gate of the cascode transistor M2 and the main transistor M1 are biased by voltages V_{b} and Vᵢₙ, respectively. The buffer is connected to a load, which is represented in the figure as having a resistive load component R_{L} and a capacitive load component C_{load}. The electrical path between the buffer and the load is referred to as a distribution line. The distribution line may include a capacitive component, which is shown in FIG. 1 as the capacitance Cₗᵢₙₑ. When the illustrated buffer is implemented as an LO buffer, the buffer is normally positioned next to the generator of the LO signal, namely, the frequency synthesizer. The distribution line thus provides an electrical path from the frequency synthesizer to the remote load. In the case of an LO buffer, the load may be an up or down conversion circuit.

The LO buffer drives the load capacitance C_{load} and the distribution line capacitance Cₗᵢₙₑ. The transfer function from the LO buffer input to the load may be approximately represented by the formula

A(s)=−gₘ₁*gₘ₂/(gₘ₂+s*C_{C})*R_{L}/(1+s*R_{L}*(C_{load}+Cₗᵢₙₑ))

where gₘ₁ and gₘ₂ are the transconductances of transistors M1 and M2, respectively, and C_{C} is a parasitic capacitance contributed by transistors M1 and M2. The value of 1/gₘ₂ is generally on the same order as R_{L}, and C_{load} is generally much greater than C_{c}, so the non-dominant pole gₘ₂/C_{c} at the cascode stage tends to be much larger than the dominant pole R_{L}*(C_{load}+Cₗᵢₙₑ). The 3 dB bandwidth of the LO buffer may be represented by the formula

W_{3dB}˜=1/R_{L}/(C_{load}+Cₗᵢₙₑ).

If a small percentage of Cₗᵢₙₑ, designated dC, is moved from the load to the M1/M2 juncture and added onto C_{c}, as shown in FIG. 1, the non-dominant pole gₘ₂/(C_{c}+dC) will be much higher than the dominant pole and the bandwidth will not be affected. However, when the dominant pole becomes R_{L}*(C_{load}+Cₗᵢₙₑ−dC), the bandwidth is effectively increased. The capacitance dC may thus be increased until the non-dominant pole has an influence comparable to the dominant pole and the maximum bandwidth is achieved. The optimum choice for dC could be approximately Cₗᵢₙₑ, which implies that when the cascode stage is moved to the load side of the buffer, as illustrated in FIG. 2, the buffer bandwidth may be increased. In this configuration, the cascode stage is positioned remotely from its normal position near the main stage, and therefore the configuration may properly be called a remote cascode topology. Thus, for a given bandwidth it is possible to save power by positioning the cascode stage of the buffer at or near the load.

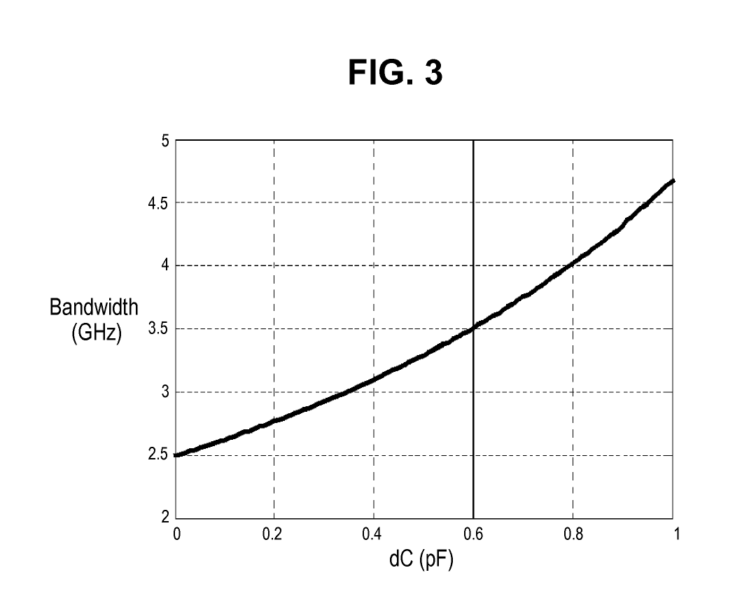

FIG. 3 is a graph illustrating the effect of changes in capacitance dC on the bandwidth of the LO buffer. For the illustrated example, Cₗᵢₙₑ=1 pF, C_{load}=1 pF, C_{c}=0.1 pF, R_{L}=200 Ohms, and gₘ₂=20 mA/V. The graph represents the 3 dB bandwidth of the LO buffer in GHz as a function of the capacitance dC in pF. As is apparent from the graph, the maximum bandwidth may be achieved when dC=1 pF=Cₗᵢₙₑ.

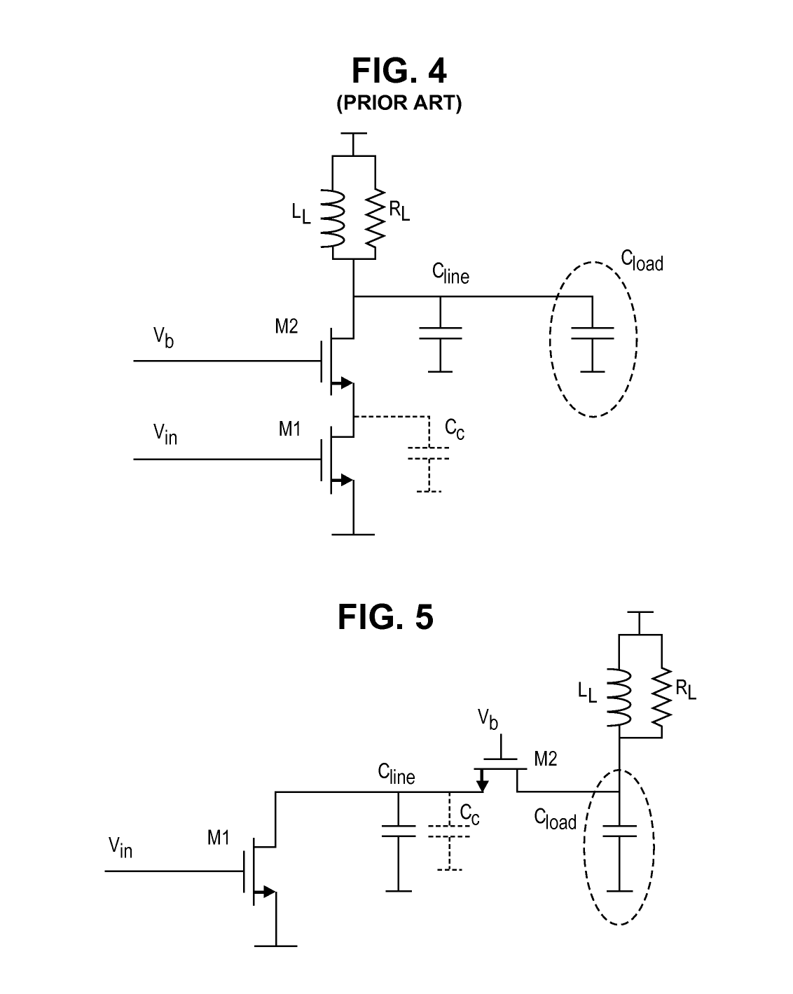

FIG. 4 illustrates a conventional NMOS common-source cascode buffer with an inductive load. The resistance R_{L} represents the parasitic resistance contributed by the inductor L_{L}. The transfer function of the buffer may be represented by the formula

A(s) 32 −gₘ₁*gₘ₂/(gₘ₂+s*C_{C})*s*R_{L}*L_{L}/(R_{L}+s*L_{L}+s\hat{0}2*R_{L}*L_{L}*(C_{load}+Cₗᵢₙₑ)).

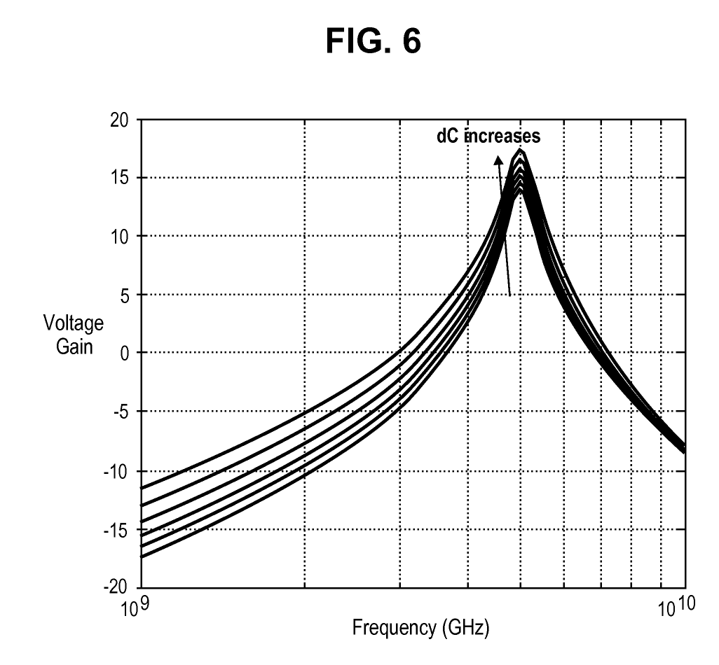

For the illustrated circuit, the inductance L_{L} may be chosen to tune out the capacitance C_{load}+Cₗᵢₙₑ by making L_{L}=1/wₒ\hat{0}2/(C_{load}+Cₗᵢₙₑ). The resistance R_{L} then equals Q*wₒ*L_{L}, where Q is the quality factor of L_{L}. If Q is assumed to be constant among inductors at wₒ, a larger L_{L} leads to a larger R_{L}, and the voltage gain is increased. Therefore, if the non-dominant pole gₘ₂/C_{C} is far away from the 3 dB frequency, it is possible to move dC from Cₗᵢₙₑ to the cascode stage to increase L_{L} as in the resistive load case. In this way, R_{L} may be increased and additional voltage gain may be obtained. The optimum point may occur at dC=Cₗᵢₙₑ, and again the remote cascode topology, as illustrate in FIG. 5, becomes the best configuration for achieving a particular gain while at the same time consuming less power.

The graph illustrated in FIG. 6 corresponds to the inductive load case illustrated in FIG. 5. For this example, it is assumed that Cₗᵢₙₑ=0.5 pF, C_{load}=0.5 pF, C_{C}=0.1 pF, gₘ₂=20 mA/V, fₒ=5 GHz and inductor Q=8. The graph represents the LO buffer transfer functions for six incremental values of dC (dC=0 to 0.5 pF in 0.1 pF steps). The maximum gain at 5 GHz is achieved at dC=0.5 pF=Cₗᵢₙₑ, and the remote cascode topology again consumes the least power for a given gain.

Contrary to the assumption made above, the inductor Q may not be constant over various inductance values. For on-chip inductors, for example, Q is likely to be larger when L is increased. However, when L is increased by a certain amount, R_{L} increases by even more, and a remote cascode topology still provides the greatest possible gain.

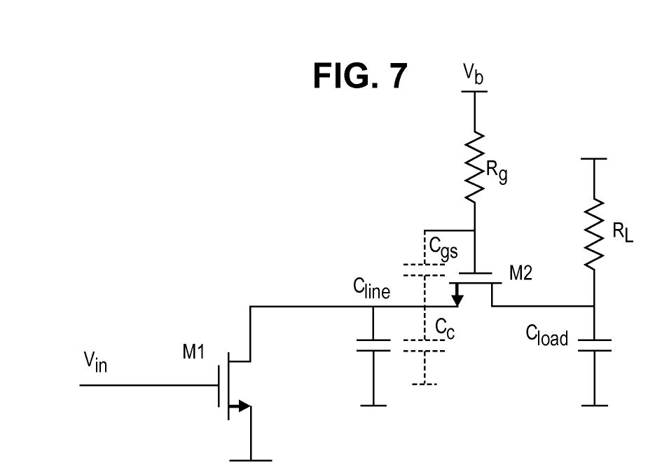

FIG. 7 illustrates a remote cascode LO buffer that is consistent with an additional embodiment of the present invention. In this embodiment, a resistance R_{g} may be added to the gate of the cascode transistor M1. For a resistive load, the transfer function of the LO buffer may then be represented by the formula

A(s)=−gₘ₁/(gₘ₂+s*(C_{c}+Cₗᵢₙₑ+C_{gs})+s\hat{0}2*((C_{gs}*(C_{c}+Cₗᵢₙₑ)*R_{g}))*R_{L}/(1+s*R_{L}*(C_{load}+Cₗᵢₙₑ)).

In this case, C_{gs} is separate from C_{c}, and the cascode stage contributes two complex poles when R_{g}>0. By properly selecting R_{g}, the bandwidth of the LO buffer may thus be extended.

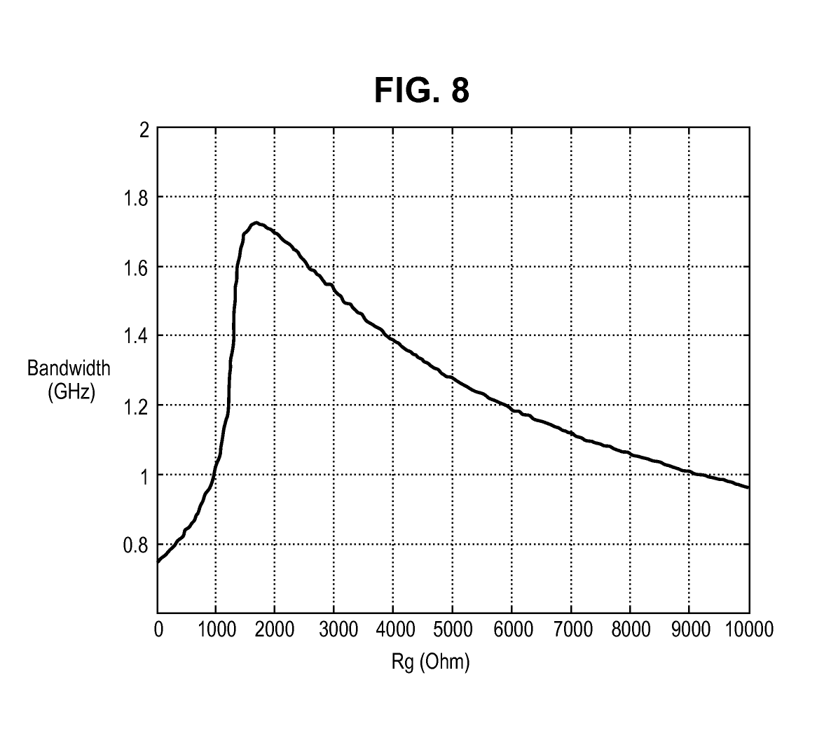

FIG. 8 illustrates 3 dB bandwidth of the LO buffer of FIG. 7 as a function of R_{g}. For this example, it is assumed that Cₗᵢₙₑ=1 pF, C_{load}=1 pF, C_{c}=0, C_{gs}=0.1 pF, R_{L}=200 Ohms, and gm2=20 mA/V. The maximum bandwidth may be achieved when R_{g}=1.7 kOhms. The resistance R_{g} may be selected to maximize the bandwidth of the LO buffer for particular circuit element values. In this way, significant power may be saved as compared to the case of R_{g}=0 Ohm. Although a resistive load has been illustrated in the example of FIG. 8, those of skill in the relevant art will appreciate that the addition of R_{g} may also be applied to buffers having an inductive load.

Although embodiments of the invention have been discussed primarily with respect to specific embodiments thereof, other variations are possible. For example, although the exemplary embodiment have been described in the context of CMOS technology, those of skill in the relevant art will appreciate that various other transistor technologies are consistent with the present invention. In addition, although not illustrated, differential circuit configurations are also suitable for use with the present invention. Moreover, steps associated with embodiments of the present invention may be performed by hardware or software, as desired. Steps can also be added to, taken from or modified from the steps in this specification without deviating from the scope of the invention. Those of skill in the relevant art will also appreciate that methods and systems consistent with the present invention are suitable for use in a wide range of communications applications, including but not limited to radio frequency identification (RFID) systems, cellular communication systems, such as TDMA, CDMA, GSM, GPRS and WCDMA systems, as well as other wireless and fixed-line communications systems and information-processing systems.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A method of buffering a signal between a circuit element and a load with a cascode buffer, comprising the steps of:
locating a cascode transistor of said cascode buffer substantially adjacent to said load and remote from a main transistor of said cascode buffer; and
transferring signals from said main transistor to said cascode transistor via a distribution line.

2. The method of claim 1 wherein said step of locating a cascode transistor further comprises connecting a source of said cascode transistor of said buffer to a drain of said main transistor of said buffer via said distribution line.

3. The method of claim 2 further comprising the step of adding a resistance to a gate of said cascode transistor, wherein a value of said resistance is selected to maximize the bandwidth of said buffer.

4. The method of claim 3 wherein said buffer comprises a local oscillator (LO) buffer.

5. The method of claim 4 wherein said LO buffer comprises a differential LO buffer.

6. The method of claim 4 wherein said load comprises a substantially capacitive load.

7. The method of claim 4 wherein said load comprises a substantially inductive load.

8. A transmitter, comprising:
a frequency synthesizer having a local oscillator (LO) that generates an LO-output signal comprising a high-frequency periodic signal;
an up-conversion circuit for up-converting signals to be transmitted by an antenna; and
a buffer circuit for buffering said LO-output signal between said frequency synthesizer and said up-conversion circuit, said buffer circuit including a main transistor, a cascode transistor and a distribution line for transferring signals over a distance;
wherein said cascode transistor of said buffer circuit is located substantially adjacent to said up-conversion circuit and substantially remote from said frequency synthesizer, and wherein said distribution line connects a drain of said main transistor to a source of said cascode transistor.

9. The transmitter of claim 8 further comprising a predetermined resistance added to a gate of said cascode transistor, said resistance being selected to maximize a bandwidth of said buffer circuit.

10. The transmitter of claim 9 wherein said transistors of said buffer circuit are formed from CMOS technology.

11. The transmitter of claim 9 wherein said buffer comprises a differential buffer.

12. The transmitter of claim 9 wherein said transistors of said buffer are formed from BJT technology.

13. A communications terminal, comprising:
a frequency synthesizer having a local oscillator (LO) that generates an LO-output signal comprising a high-frequency periodic signal;
a down-conversion circuit for down-converting signals received by an antenna; and
a buffer circuit for buffering said LO-output signal between said frequency synthesizer and said down-conversion circuit, said buffer circuit including a main transistor, a cascode transistor and a distribution line for transferring signals over a distance;
wherein said cascode transistor of said buffer circuit is located substantially adjacent to said down-conversion circuit and substantially remote from said frequency synthesizer, and wherein said distribution line connects a drain of said main transistor to a source of said cascode transistor.

14. The communications terminal of claim 13 further comprising a predetermined resistance added to a gate of said cascode transistor, said resistance being selected to maximize a bandwidth of said buffer circuit.

15. The communications terminal of claim 14 wherein said transistors of said buffer circuit are formed from CMOS technology.

16. The communications terminal of claim 14 wherein said buffer circuit comprises a differential buffer.
